(19) United States
(12) Patent Application Publication
(10) Pub. No.: US 2026/0088078 A1
(43) Pub. Date: Mar. 26, 2026

(54) SEMICONDUCTOR DEVICE

(71) Applicant: SAMSUNG ELECTRONICS CO.,LTD., Suwon-si (KR)

(72) Inventor: Jee Woong KIM, Suwon-si (KR)

(73) Assignee: SAMSUNG ELECTRONICS CO.,LTD., Suwon-si (KR)

(21) Appl. No.: 19/197,129

(22) Filed: May 2, 2025

(30) Foreign Application Priority Data
Sep. 25, 2024 (KR) 10-2024-0129801

(51) Int. Cl. G11C 11/412; H01L 23/528; H10B 10/00

(52) U.S. Cl. CPC G11C 11/412; H10B 10/12; H10W 20/427

(57) ABSTRACT

A semiconductor device is provided. The semiconductor device includes: a first word line on a first surface of a substrate; a second word line on a second surface of the substrate; a first cell and a second cell, which are adjacent to each other the second direction, on the substrate. Each of the first and second cells includes first and second inverters, a first pass transistor connecting the first inverter with a bit line, and a second pass transistor connecting the second inverter with a complementary bit line. The first word line is connected to a gate of the first pass transistor of the first cell and a gate of the second pass transistor of the first cell. The second word line is connected to a gate of the first pass transistor of the second cell and a gate of the second pass transistor of the second cell.

### CROSS-REFERENCE TO RELATED APPLICATION

This application claims priority from Korean Patent Application No. 10-2024-0129801, filed on Sep. 25, 2024, in the Korean Intellectual Property Office, the disclosure of which is incorporated by reference herein in its entirety.

### BACKGROUND

### Field

The present disclosure relates to a semiconductor device, and more particularly, to a semiconductor device that includes a static random access memory (SRAM) device.

### Description of Related Art

Semiconductor devices allow for miniaturization, multi-functionalization and/or low fabricating costs. The semiconductor devices include a semiconductor memory device for storing logic data, a semiconductor logic device for processing logic data, and a hybrid semiconductor device including a memory element and a logic element.

There is an increasing demand for improved characteristics of the semiconductor device. For example, there is a demand for increased reliability, increased speed, increased multi-functionalization for the semiconductor device. In order to fulfil these requirements, structures in the semiconductor device have been increasingly complicated and highly integrated. For this reason, there is a problem that delay occurs in transfer of an electrical signal through a wiring.

### BRIEF SUMMARY

One or more embodiments provide a semiconductor device having improved performance.

The objects of the present disclosure are not limited to those mentioned above and additional objects of the present disclosure, which are not mentioned herein, will be clearly understood by those skilled in the art from the following description.

According to an aspect of an embodiment, a semiconductor device includes: a substrate including a first surface and a second surface, which are opposite to each other; a first word line extending along a first direction on the first surface; a second word line extending along the first direction on the second surface; a bit line and a complementary bit line, which extend in parallel along a second direction that crosses the first direction, on the substrate; and a first cell and a second cell, which are adjacent to each other along the second direction, on the substrate. Each of the first cell and the second cell includes a latch circuit including a first inverter and a second inverter, a first pass transistor connecting an output node of the first inverter with the bit line, and a second pass transistor connecting an output node of the second inverter with the complementary bit line. The first word line is connected to a gate of the first pass transistor of the first cell and a gate of the second pass transistor of the first cell. The second word line is connected to a gate of the first pass transistor of the second cell and a gate of the second pass transistor of the second cell.

According to another aspect of an embodiment, a semiconductor device includes: a substrate including a first surface and a second surface, which are opposite to each other; a plurality of unit static random access memory (SRAM) cells arranged in a matrix along first and second directions crossing each other, on the first surface; a first word line extending along the first direction on the first surface; and a second word line extending along the first direction on the second surface. The plurality of unit SRAM cells include first unit SRAM cells arranged in a first row and second unit SRAM cells arranged in a second row, each of the first and second rows extending along the first direction. The first word line is commonly connected to the first unit SRAM cells of the first row. The second word line is commonly connected to the second unit SRAM cells of the second row.

According to another aspect of an embodiment, a semiconductor device includes first and second cells adjacent to each other along a first direction; a substrate including a first surface and a second surface, which are opposite to each other; first to fourth active patterns, which are sequentially arranged along a second direction crossing the first direction, each of the first to fourth active patterns extending along the first direction on the first surface; a first gate structure, which extends along the second direction across the first active pattern, in the first cell; a second gate structure, which extends along the second direction across the third and fourth active patterns, in the first cell; a third gate structure, which extends along the second direction across the first and second active patterns, in the first cell; a fourth gate structure, which extends along the second direction across the fourth active pattern, in the first cell; a first source/drain contact, which connects the first active pattern with the second active pattern and the second gate structure, between the first gate structure and the third gate structure, and between the second gate structure and the third gate structure; a second source/drain contact, which connects the third active pattern with the fourth active pattern and the third gate structure, between the second gate structure and the third gate structure, and between the second gate structure and the fourth gate structure; a fifth gate structure, which extends along the second direction across the first active pattern, in the second cell; a sixth gate structure, which extends along the second direction across the third and fourth active patterns, in the second cell; a seventh gate structure, which extends along the second direction across the first and second active patterns, in the second cell; an eighth gate structure, which extends along the second direction across the fourth active pattern, in the second cell; a third source/drain contact, which connects the first active pattern with the second active pattern and the sixth gate structure, between the fifth gate structure and the seventh gate structure, and between the sixth gate structure and the seventh gate structure; a fourth source/drain contact, which connects the third active pattern with the fourth active pattern and the seventh gate structure, between the sixth gate structure and the seventh gate structure, and between the sixth gate structure and the eighth gate structure; a first frontside wiring pattern, which extends along the second direction and is connected to the first and fourth gate structures, on the first surface; and a first backside wiring pattern, which extends along the second direction and is connected to the fifth and eighth gate structures, on the second surface.

### BRIEF DESCRIPTION OF DRAWINGS

The above and other aspects and features will be more apparent from the following description of embodiments, taken in conjunction with the attached drawings, in which:

FIG. 1 is a block diagram illustrating a semiconductor device according to some embodiments.

FIG. 2 is a circuit view illustrating a semiconductor device according to some embodiments.

FIG. 3 is a layout view illustrating a semiconductor device according to some embodiments.

FIG. 4 is a schematic cross-sectional view taken along line A-A of FIG. 3.

FIG. 5 is a schematic cross-sectional view taken along line B-B of FIG. 3.

FIG. 6 is a schematic cross-sectional view taken along line C-C of FIG. 3.

FIG. 7 is a schematic cross-sectional view taken along line D-D of FIG. 3.

FIG. 8 is a schematic cross-sectional view taken along line E-E of FIG. 3.

FIGS. 9 to 11 are layout views illustrating a semiconductor device according to some embodiments.

FIG. 12 is a layout view illustrating a semiconductor device according to some embodiments.

FIG. 13 is a schematic cross-sectional view taken along line F-F of FIG. 12.

FIG. 14 is a schematic cross-sectional view taken along line G-G of FIG. 12.

FIG. 15 is a circuit view illustrating a semiconductor device according to some embodiments.

FIG. 16 is a layout view illustrating a semiconductor device according to some embodiments.

### DETAILED DESCRIPTION

Hereinafter, embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure.

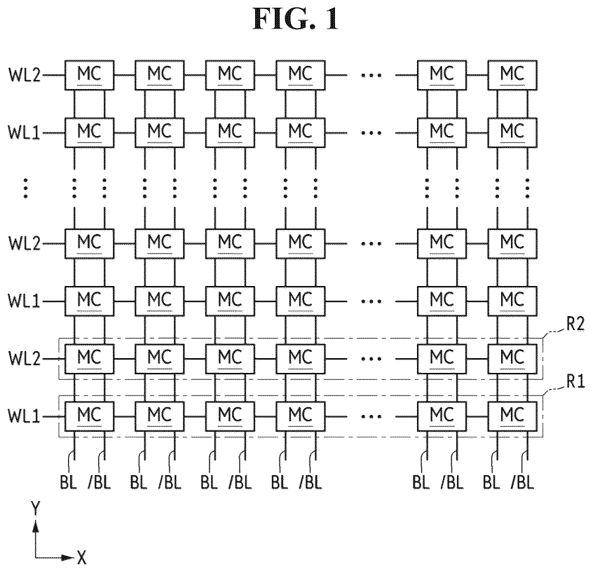

FIG. 1 is a block diagram illustrating a semiconductor device according to some embodiments.

Referring to FIG. 1, the semiconductor device according to some embodiments includes a plurality of unit static random access memory (SRAM) cells MC, a first word line WL1, a second word line WL2, a bit line BL, and a complementary bit line/BL.

The plurality of unit SRAM cells MC may be two-dimensionally arranged. For example, the plurality of unit SRAM cells MC may be arranged in the form of a matrix along a first direction X and a second direction Y, which cross each other.

The plurality of unit SRAM cells MC may include a first row R1 and a second row R2. Each of the first row R1 and the second row R2 may include unit SRAM cells MC of one row, which are arranged along the first direction X. The first row R1 and the second row R2 may be arranged along the second direction Y. In some embodiments, the first row R1 and the second row R2 may be arranged alternately along the second direction Y. In this regard, the semiconductor device may include a plurality of first word lines WL1 and a plurality of second word lines WL2 that are alternately provided along the second direction Y.

Each of the first word line WL1 and the second word line WL2 may extend in the first direction X. The first word line WL1 may be connected in common to the unit SRAM cells MC of the first row R1. The second word line WL2 may be connected in common to the unit SRAM cells MC of the second row R2. In some embodiments, the first word line WL1 and the second word line WL2 may be alternately arranged along the second direction Y.

The bit line BL and the complementary bit line/BL may extend in parallel in the second direction Y. One bit line BL and one complementary bit line/BL, which are adjacent to each other, may form a pair. A pair of the bit line BL and the complementary bit line/BL may extend in the second direction Y, and thus may be connected in common to the unit SRAM cells MC of one column, which are arranged along the second direction Y, among the plurality of unit SRAM cells MC. For example, a pair of the bit line BL and the complementary bit line/BL may be connected in common to the first row R1 and the second row R2.

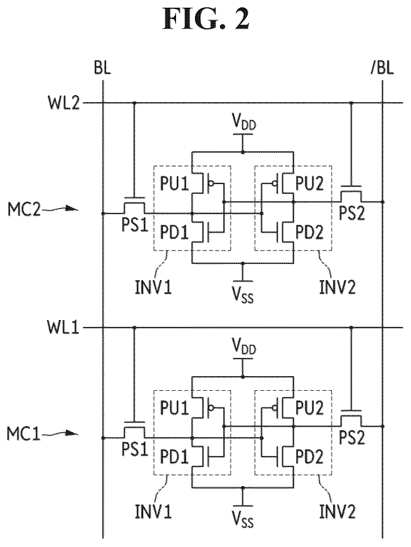

FIG. 2 is a circuit view illustrating a semiconductor device according to some embodiments.

Referring to FIGS. 1 and 2, the semiconductor device according to some embodiments includes a first cell MC1 and a second cell MC2, which are adjacent to each other.

Each of the first cell MC1 and the second cell MC2 may correspond to one of a plurality of unit SRAM cells MC. The first cell MC1 and the second cell MC2 may be adjacent to each other in the second direction Y. The first cell MC1 may be one of the plurality of unit SRAM cells MC in the first row R1. The second cell MC2 may be one of the plurality of unit SRAM cells MC in the second row R2.

Each of the first cell MC1 and the second cell MC2 may include a pair of inverters INV1 and INV2 connected in parallel between a power node VDD and a ground node V_{SS}, and a first pass transistor PS1 and a second pass transistor PS2, which are connected to output nodes of the inverters INV1 and INV2.

To configure one latch circuit, an input node of the first inverter INV1 may be connected to the output node of the second inverter INV2, and an input node of the second inverter INV2 may be connected to the output node of the first inverter INV1.

The first inverter INV1 may include a first pull-up transistor PU1 and a first pull-down transistor PD1, which are connected in series between the power node VDD and the ground node V_{SS}. The second inverter INV2 may include a second pull-up transistor PU2 and a second pull-down transistor PD2, which are connected in series between the power node VDD and the ground node V_{SS}. Each of the first pull-up transistor PU1 and the second pull-up transistor PU2 may be a P-type field effect transistor (PFET), and each of the first pull-down transistor PD1 and the second pull-down transistor PD2 may be an N-type field effect transistor (NFET).

The first pass transistor PS1 may connect the bit line BL to the output node of the first inverter INV1. The second pass transistor PS2 may connect the complementary bit line/BL to the output node of the second inverter INV2.

The first word line WL1 may be connected to a gate of the first pass transistor PS1 of the first cell MC1 and a gate of the second pass transistor PS2 of the first cell MC1. The second word line WL2 may be connected to a gate of the first pass transistor PS1 of the second cell MC2 and a gate of the second pass transistor PS2 of the second cell MC2.

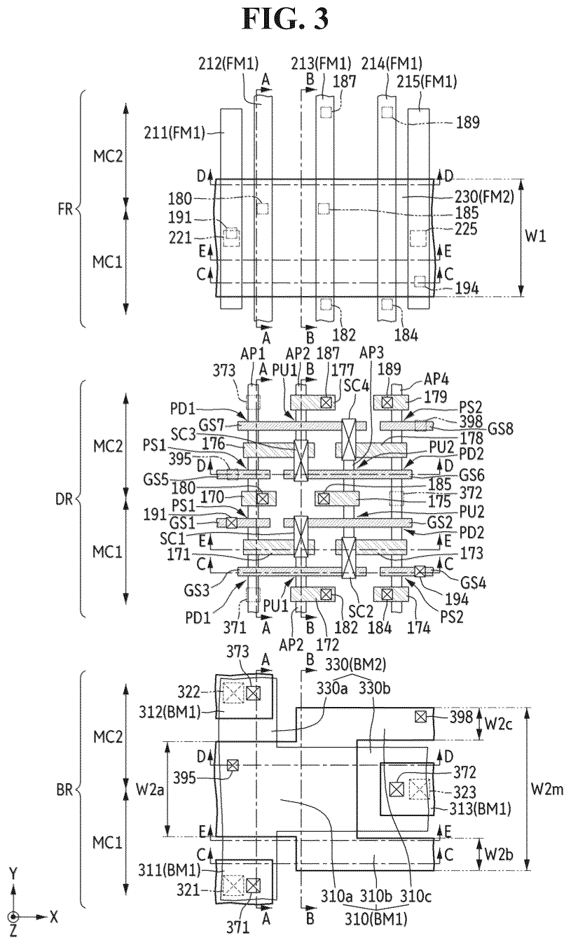

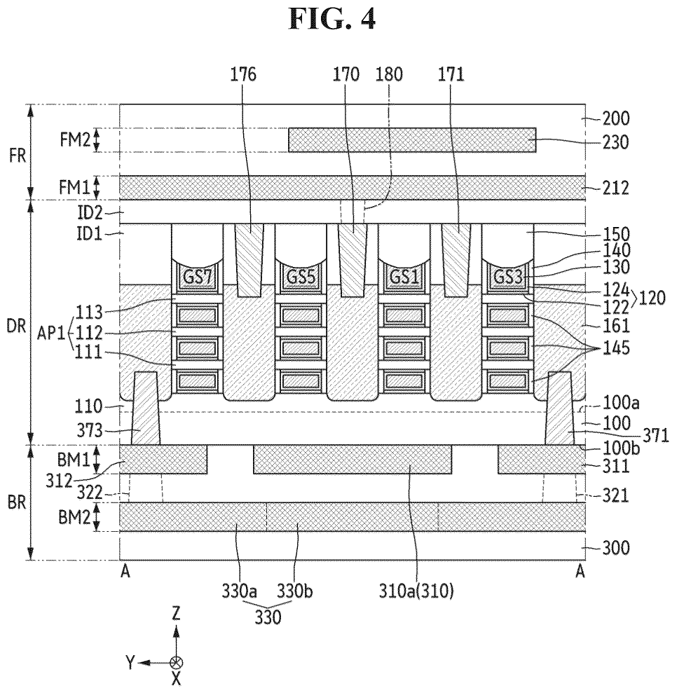

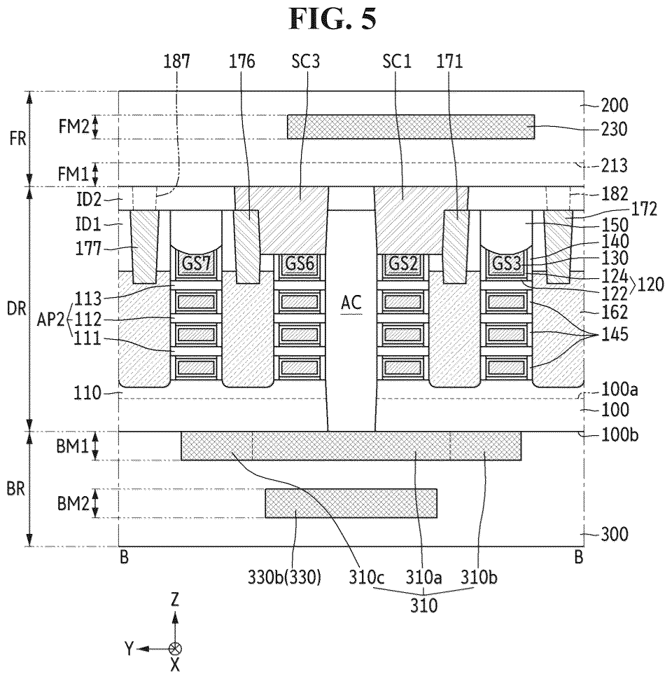

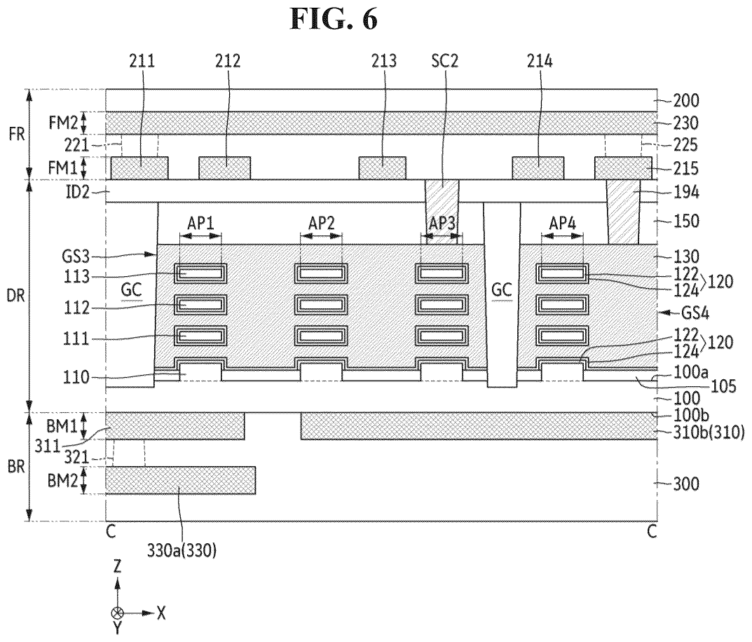

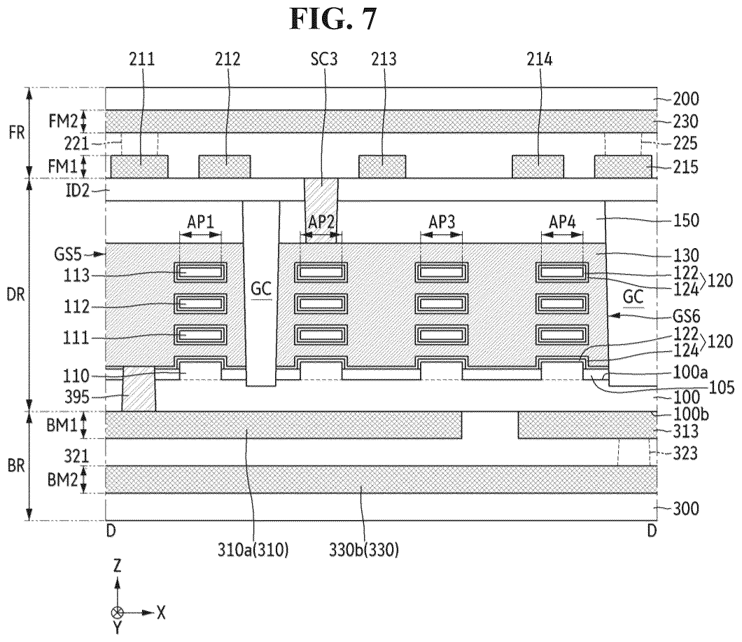

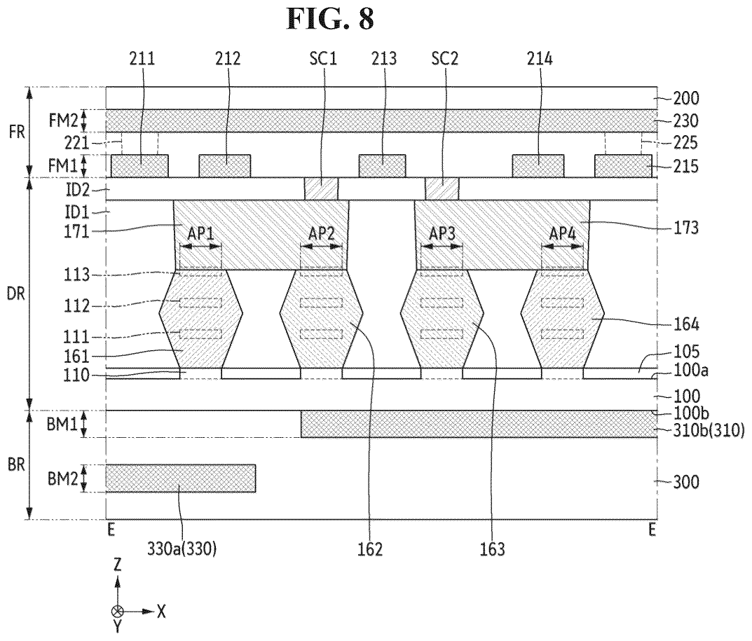

FIG. 3 is a layout view illustrating a semiconductor device according to some embodiments. FIG. 4 is a schematic cross-sectional view taken along line A-A of FIG. 3. FIG. 5 is a schematic cross-sectional view taken along line B-B of FIG. 3. FIG. 6 is a schematic cross-sectional view taken along line C-C of FIG. 3. FIG. 7 is a schematic cross-sectional view taken along line D-D of FIG. 3. FIG. 8 is a schematic cross-sectional view taken along line E-E of FIG. 3.

Referring to FIGS. 1 to 8, the semiconductor device according to some embodiments includes a device region DR, a frontside region FR, and a backside region BR.

The device region DR may include a first cell MC1 and a second cell MC2, which are formed on substrate 100. The first cell MC1 and the second cell MC2 may be adjacent to each other in the second direction Y. The device region DR may include the substrate 100, a field insulating film 105, first to fourth active patterns AP1 to AP4, first to eighth gate structures GS1 to GS8, first to fourth source/drain regions 161 to 164, first to tenth source/drain contacts 170 to 179, a first interlayer insulating film ID1, and a second interlayer insulating film ID2.

The substrate 100 may be a bulk silicon or a silicon-on-insulator (SOI). Alternatively, the substrate 100 may be a silicon substrate, or may include another material, for example, silicon germanium, silicon germanium on insulator (SGOI), indium antimonide, lead telluride, indium arsenide, indium phosphide, gallium arsenide or gallium antimonide. The bulk semiconductor pattern 110 may be formed by etching a portion of a base substrate, or may be an epitaxial layer formed on the base substrate.

In some embodiments, the substrate 100 may be an insulating substrate containing an insulating material. For example, the substrate 100 may include at least one of silicon oxide, silicon oxynitride, silicon oxynitride or a combination thereof, but embodiments are not limited thereto. For example, the substrate 100 may include a silicon oxide film.

The substrate 100 may include a first surface 100a and a second surface 100b, which are opposite to each other. In the following description, the first surface 100a may be also referred to as a front side of the substrate 100, and the second surface 100b may be also referred to as a back side of the substrate 100.

The first to fourth active patterns AP1 to AP4 may be formed on the first surface 100a. The first to fourth active patterns AP1 to AP4 may be sequentially arranged along the first direction X. The first to fourth active patterns AP1 to AP4 may extend to be long in the second direction and may be spaced apart from one another in the first direction X. The first to fourth active patterns AP1 to AP4 may extend over the first cell MC1 and the second cell MC2, respectively.

Each of the first to fourth active patterns AP1 to AP4 may include silicon (Si) or germanium (Ge), which is an element semiconductor material. Alternatively, each of the first to fourth active patterns AP1 to AP4 may include a compound semiconductor, for example, a group IV-IV compound semiconductor or a group III-V compound semiconductor. The group IV-IV compound semiconductor may be a binary compound or ternary compound, which includes at least two of carbon (C), silicon (Si), germanium (Ge) or tin (Sn), or a compound including at least two of carbon (C), silicon (Si), germanium (Ge) or tin (Sn), which are doped with a group IV element. The group III-V compound semiconductor may be, for example, one of a binary compound, a ternary compound or a quaternary compound, which is formed by combination of at least one of aluminum (Al), gallium (Ga) or indium (In), which is a group III element, and at least one of phosphorus (P), arsenic (As) or antimony (Sb), which is a group V element.

In some embodiments, the first active pattern AP1 and the fourth active pattern AP4 may be used as channel regions of the NFET, and the second active pattern AP2 and the third active pattern AP3 may be used as channel regions of the PFET.

In some embodiments, each of the first to fourth active patterns AP1 to AP4 may include a plurality of bridge patterns 111 to 113 on the substrate 100. The plurality of bridge patterns 111 to 113 may be sequentially stacked along a vertical direction (e.g., a third direction Z crossing the first direction X and the second direction Y), and thus may be spaced apart from one another. The first to fourth active patterns AP1 to AP4 may be used as channel regions of a multi-bridge-channel field effect transistor (MBCFET®) including a multi-bridge channel. The number of bridge patterns 111 to 113 included in each of the first to fourth active patterns AP1 to AP4 is provided as an example, and embodiments are not limited to the shown example.

In some embodiments, a fin pattern 110 may be formed between the substrate 100 and the bridge patterns 111 to 113. The fin pattern 110 may protrude from the first surface 100a of the substrate 100 and extend in the second direction Y. In some embodiments, the fin pattern 110 may be an insulating pattern containing an insulating material.

In some embodiments, the second active pattern AP2 of the first cell MC1 may be separated from the second active pattern AP2 of the second cell MC2. For example, a separation pattern AC may be formed between the second active pattern AP2 of the first cell MC1 and the second active pattern AP2 of the second cell MC2. The separation pattern AC may extend in the first direction X at a boundary between the first cell MC1 and the second cell MC2 to separate the second active pattern AP2 of the first cell MC1 from the second active pattern AP2 of the second cell MC2.

The separation pattern AC may include an insulating material, for example, at least one of silicon oxide, silicon nitride, silicon oxynitride, silicon oxycarbide, silicon boron nitride, silicon boron carbonitride, silicon oxycarbonitride or a combination thereof, but embodiments are not limited thereto.

In some embodiments, the first to fourth active patterns AP1 to AP4 may be arranged in a planar symmetry relationship with respect to a boundary surface (e.g., XZ plane) between the first cell MC1 and the second cell MC2.

The field insulating film 105 may be formed on the substrate 100. In some embodiments, the field insulating film 105 may cover at least a portion of a side of the fin pattern 110. The field insulating film 105 may include, for example, at least one of silicon oxide, silicon nitride, silicon oxynitride or a combination thereof, but embodiments are not limited thereto.

The first to eighth gate structures GS1 to GS8 may be formed on the substrate 100 and the field insulating film 105. Each of the first to eighth gate structures GS1 to GS8 may extend to be long in the first direction X. The first to eighth gate structures GS1 to GS8 may cross the first to fourth active patterns AP1 to AP4. For example, the bridge patterns 111 to 113 may extend in the second direction Y to pass through the first to eighth gate structures GS1 to GS8. The first to fourth gate structures GS1 to GS4 may be disposed in the first cell MC1. The fifth to eighth gate structures GS5 to GS8 may be disposed in the second cell MC2.

The first gate structure GS1 may cross the first active pattern AP1. The first gate structure GS1 may be provided as the gate of the first pass transistor PS1 of the first cell MC1. That is, the region of the first active pattern AP1, which crosses the first gate structure GS1, may be provided as a channel region of the first pass transistor PS1 of the first cell MC1.

The second gate structure GS2 may be spaced apart from the first gate structure GS1 in the first direction X. The second gate structure GS2 may cross the third active pattern AP3 and the fourth active pattern AP4. The second gate structure GS2 may be provided as a gate of the second inverter INV2 of the first cell MC1. For example, the region of the third active pattern AP3, which crosses the second gate structure GS2, may be provided as a channel region of the second pull-up transistor PU2 of the first cell MC1, and the region of the fourth active pattern AP4, which crosses the second gate structure GS2, may be provided as a channel region of the second pull-down transistor PD2 of the first cell MC1.

The third gate structure GS3 may be spaced apart from the first gate structure GS1 and the second gate structure GS2 in the second direction Y. The third gate structure GS3 may cross the first active pattern AP1 and the second active pattern AP2. The third gate structure GS3 may be provided as a gate of a first inverter INV1 of the first cell MC1. For example, the region of the first active pattern AP1, which crosses the third gate structure GS3, may be provided as a channel region of the first pull-down transistor PD1 of the first cell MC1, and the region of the second active pattern AP2, which crosses the third gate structure GS3, may be provided as a channel region of the first pull-up transistor PU1 of the first cell MC1.

The fourth gate structure GS4 may be spaced apart from the third gate structure GS3 in the first direction X. The fourth gate structure GS4 may cross the fourth active pattern AP4. The fourth gate structure GS4 may be provided as a gate of the second pass transistor PS2 of the first cell MC1. That is, the region of the fourth active pattern AP4, which crosses the fourth gate structure GS4, may be provided as a channel region of the second pass transistor PS2 of the first cell MC1.

The fifth gate structure GS5 may cross the first active pattern AP1. The fifth gate structure GS5 may be provided as a gate of the first pass transistor PS1 of the second cell MC2. That is, the region of the first active pattern AP1, which crosses the fifth gate structure GS5, may be provided as a channel region of the first pass transistor PS1 of the second cell MC2.

The sixth gate structure GS6 may be spaced apart from the fifth gate structure GS5 in the first direction X. The sixth gate structure GS6 may cross the third active pattern AP3 and the fourth active pattern AP4. The sixth gate structure GS6 may be provided as a gate of the second inverter INV2 of the second cell MC2. For example, the region of the third active pattern AP3, which crosses the sixth gate structure GS6, may be provided as a channel region of the second pull-up transistor PU2 of the second cell MC2, and the region of the fourth active pattern AP4, which crosses the sixth gate structure GS6, may be provided as a channel region of the second pull-down transistor PD2 of the second cell MC2.

The seventh gate structure GS7 may be spaced apart from the fifth gate structure GS5 and the sixth gate structure GS6 in the second direction Y. The seventh gate structure GS7 may cross the first active pattern AP1 and the second active pattern AP2. The seventh gate structure GS7 may be provided as a gate of the first inverter INV1 of the second cell MC2. For example, the region of the first active pattern AP1, which crosses the seventh gate structure GS7, may be provided as a channel region of the first pull-down transistor PD1 of the second cell MC2, and the region of the second active pattern AP2, which crosses the seventh gate structure GS7, may be provided as a channel region of the first pull-up transistor PU1 of the second cell MC2.

The eighth gate structure GS8 may be spaced apart from the seventh gate structure GS7 in the first direction X. The eighth gate structure GS8 may cross the fourth active pattern AP4. The eighth gate structure GS8 may be provided as a gate of the second pass transistor PS2 of the second cell MC2. That is, the region of the fourth active pattern AP4, which crosses the eighth gate structure GS8, may be provided as a channel region of the second pass transistor PS2 of the second cell MC2.

In some embodiments, a width of each of the first cells MC1 and the second cells MC2 in the second direction Y may be about 2 contacted poly pitch (CPP). In this case, the CPP refers to a unit arrangement interval between gate structures arranged along the second direction Y. For example, 1 CPP may be defined as a sum of an interval between gate structures (e.g., the first gate structure GS1 and the third gate structure GS3) adjacent to each other in the second direction Y and a width of one (e.g., the first gate structure GS1) of the gate structures. Alternatively, for example, 1 CPP may be defined as an interval along the second direction Y between a center line of one gate structure (e.g., the first gate structure GS1) and a center line of another gate structure (e.g., the third gate structure GS3) adjacent thereto, the center lines extending in the first direction X.

Each of the first to eighth gate structures GS1 to GS8 may include a gate dielectric film 120, a gate electrode 130, a gate spacer 140, and a gate capping layer 150.

The gate dielectric film 120 may be interposed between each of the first to fourth active patterns AP1 to AP4 and the gate electrode 130. The gate dielectric film 120 may be interposed between the field insulating film 105 and the gate electrode 130. In some embodiments, the gate dielectric film 120 may be interposed between the fin pattern 110 and the gate electrode 130.

The gate dielectric film 120 may include at least one of, for example, silicon oxide, silicon oxynitride, silicon nitride, or a high dielectric constant material (i.e., a high-K dielectric) having a dielectric constant greater than that of silicon oxide. The high dielectric constant material may include, for example, hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}) or a combination thereof, but embodiments are not limited thereto.

In some embodiments, the gate dielectric film 120 may include an interfacial film 122 and a high dielectric film 124, which are sequentially stacked on the first to fourth active patterns AP1 to AP4.

The interfacial film 122 may surround a circumference of each of the bridge patterns 111 to 113. For example, the interfacial film 122 may conformally extend along the circumference of each of the bridge patterns 111 to 113. The interfacial film 122 may extend along a surface of the fin pattern 110, which is exposed from the field insulating film 105. In some embodiments, the interfacial film 122 may include an oxide film formed by oxidizing a surface of each of the bridge patterns 111 to 113. For example, when each of the bridge patterns 111 to 113 is a silicon (Si) pattern, the interfacial film 122 may include a silicon oxide film.

The high dielectric film 124 may surround the periphery of the interfacial film 122. In some embodiments, a portion of the high dielectric film 124 may be interposed between the gate electrode 130 and the gate spacer 140. For example, the high dielectric film 124 may conformally extend along a profile of the periphery of the interfacial film 122 and an inner side of the gate spacer 140. Also, the high dielectric film 124 may be further extended along an upper surface of the field insulating film 105. The high dielectric film 124 may include a high dielectric constant material having a dielectric constant greater than that of silicon oxide.

The gate electrode 130 may extend to be long in the first direction X to cross the first to fourth active patterns AP1 to AP4. Each of the bridge patterns 111 to 113 may extend in the second direction Y to pass through the gate electrode 130. The gate electrode 130 may include a conductive material, for example, at least one of TiN, WN, TaN, Ru, TiC, TaC, Ti, Ag, Al, TiAl, TiAIN, TiAIC, TaCN, TaSiN, Mn, Zr, W, Al or a combination thereof, but embodiments are not limited thereto. The gate electrode 130 may be formed by a replacement process, but embodiments are not limited thereto.

The gate electrode 130 is shown as only a single layer, but embodiments are not limited thereto. For example, the gate electrode 130 may be a multi-layer formed by stacking a plurality of conductive layers. For example, the gate electrode 130 may include a work function adjustment layer for adjusting a work function and a filling conductive layer for filling a space formed by the work function adjustment layer. The work function adjustment layer may include at least one of, for example, TiN, TaN, TiC, TaC, TiAIC or a combination thereof. The filling conductive layer may include, for example, W or Al.

The gate spacer 140 may extend along a side of the gate electrode 130. Each of the bridge patterns 111 to 113 may extend in the second direction Y to pass through the gate spacer 140. The gate spacer 140 may include an insulating material, for example, at least one of silicon oxide, silicon nitride, silicon oxynitride, silicon oxycarbide, silicon boron nitride, silicon boron carbonitride, silicon oxycarbonitride or a combination thereof, but embodiments are not limited thereto.

The gate capping layer 150 may extend along an upper surface of the gate electrode 130. The gate capping layer 150 may include an insulating material, for example, at least one of silicon oxide, silicon nitride, silicon oxynitride, silicon oxycarbide, silicon boron nitride, silicon boron carbonitride, silicon oxycarbonitride or a combination thereof, but embodiments are not limited thereto.

In some embodiments, each of the first to eighth gate structures GS1 to GS8 may further include an inner spacer 145. The inner spacer 145 may be formed on the side of the gate electrode 130 between the bridge patterns 111 to 113. The inner spacer 145 may be formed on the side of the gate electrode 130 between the fin pattern 110 and the bridge patterns 111 to 113. The inner spacer 145 may include an insulating material, for example, at least one of silicon oxide, silicon nitride, silicon oxynitride, silicon oxycarbide, silicon boron nitride, silicon boron carbonitride, silicon oxycarbonitride or a combination thereof, but embodiments are not limited thereto.

In some embodiments, the first to eighth gate structures GS1 to GS8 may be separated by a cutting pattern GC. For example, the cutting pattern GC may extend in the second direction Y between the first active pattern AP1 and the second active pattern AP2 to separate the first gate structure GS1 from the second gate structure GS2, and separate the fifth gate structure GS5 from the sixth gate structure GS6. For example, the cutting pattern GC may extend in the second direction Y between the third active pattern AP3 and the fourth active pattern AP4 in the first cell MC1 to separate the third gate structure GS3 from the fourth gate structure GS4. For example, the cutting pattern GC may extend in the second direction Y between the third active pattern AP3 and the fourth active pattern AP4 in the second cell MC2 to separate the seventh gate structure GS7 from the eighth gate structure GS8.

The cutting pattern GC may include an insulating material, for example, at least one of silicon oxide, silicon nitride, silicon oxynitride, silicon oxycarbide, silicon boron nitride, silicon boron carbonitride, silicon oxycarbonitride or a combination thereof, but embodiments are not limited thereto.

In some embodiments, the first to eighth gate structures GS1 to GS8 may be arranged in a planar symmetry relationship with respect to the boundary surface (e.g., XZ plane) between the first cell MC1 and the second cell MC2.

The first to fourth source/drain regions 161 to 164 may be formed in the first to fourth active patterns AP1 to AP4, respectively. In the present specification, the first to fourth source/drain regions 161 to 164 may be described as elements included in the first to fourth active patterns AP1 to AP4, or may be described as separate elements different from the first to fourth active patterns AP1 to AP4.

For example, the first active pattern AP1 may include a first source/drain region 161. The first source/drain region 161 may be formed in the first active pattern AP1 on sides of the first, third, fifth and seventh gate structures GS1, GS3, GS5 and GS7.

For example, the second active pattern AP2 may include a second source/drain region 162. The second source/drain region 162 may be formed in the second active pattern AP2 on sides of the second, third, sixth and seventh gate structures GS2, GS3, GS6, and GS7.

For example, the third active pattern AP3 may include a third source/drain region 163. The third source/drain region 163 may be formed in the third active pattern AP3 on sides of the second, third, sixth and seventh gate structures GS2, GS3, GS6, and GS7.

For example, the fourth active pattern AP4 may include a fourth source/drain region 164. The fourth source/drain region 164 may be formed in the fourth active pattern AP4 on sides of the second, fourth, sixth and eighth gate structures GS2, GS4, GS6 and GS8.

Each of the bridge patterns 111 to 113 may be connected to the first to fourth source/drain regions 161 to 164 by passing through the gate electrode 130 and the gate spacer 140. The first to fourth source/drain regions 161 to 164 may be separated from the gate electrode 130 by the gate dielectric film 120, the gate spacer 140 and/or the inner spacer 145.

In some embodiments, each of the first to fourth source/drain regions 161 to 164 may include an epitaxial layer doped with impurities. For example, each of the first to fourth source/drain regions 161 to 164 may include an epitaxial pattern grown from the first to fourth active patterns AP1 to AP4 by an epitaxial growth method.

When the first active pattern AP1 and the fourth active pattern AP4 are the channel regions of the NFET, the first source/drain region 161 and the fourth source/drain region 164 may include N-type impurities (e.g., P, Sb or As) or impurities for preventing diffusion of the N-type impurities.

When the second active pattern AP2 and the third active pattern AP3 are the channel regions of the PFET, each of the second source/drain region 162 and the third source/drain region 163 may include P-type impurities (e.g., B, In, Ga or Al) or impurities for preventing diffusion of the P-type impurities.

The first to tenth source/drain contacts 170 to 179 may be connected to the first to fourth source/drain regions 161 to 164. Accordingly, the first to tenth source/drain contacts 170 to 179 may be electrically connected to the first to fourth active patterns AP1 to AP4. The shape and arrangement of the first to tenth source/drain contacts 170 to 179 are provided as example, and embodiments are not limited to the shown example.

The first source/drain contact 170 may be connected to the first active pattern AP1. For example, the first source/drain contact 170 may be in contact with the first source/drain region 161 between the first gate structure GS1 and the fifth gate structure GS5. In some embodiments, the first source/drain contact 170 may be disposed at the boundary between the first cell MC1 and the second cell MC2. The first cell MC1 and the second cell MC2 may share the first source/drain contact 170.

The second source/drain contact 171 may be interposed between the first gate structure GS1 and the third gate structure GS3, and between the second gate structure GS2 and the third gate structure GS3. The second source/drain contact 171 may connect the first active pattern AP1 with the second active pattern AP2. For example, the second source/drain contact 171 may extend in the first direction X to contact both the first source/drain region 161 and the second source/drain region 162.

The second source/drain contact 171 may be electrically connected to the second gate structure GS2. For example, a first shared contact SC1 may be formed on the second gate structure GS2 and the second source/drain contact 171. The first shared contact SC1 may extend in the second direction Y to connect the gate electrode 130 of the second gate structure GS2 with the second source/drain contact 171. An output node (i.e., the second source/drain contact 171) of the first inverter INV1 of the first cell MC1 may be connected to an input node (i.e., the second gate structure GS2) of the second inverter INV2 of the first cell MC1 through the first shared contact SC1.

The third source/drain contact 172 may be connected to the second active pattern AP2. For example, the third source/drain contact 172 may be in contact with the second source/drain region 162 on one side of the third gate structure GS3. The third gate structure GS3 may be interposed between the second source/drain contact 171 and the third source/drain contact 172.

The fourth source/drain contact 173 may be interposed between the second gate structure GS2 and the third gate structure GS3, and between the second gate structure GS2 and the fourth gate structure GS4. The fourth source/drain contact 173 may connect the third active pattern AP3 with the fourth active pattern AP4. For example, the fourth source/drain contact 173 may extend in the first direction X to contact both the third source/drain region 163 and the fourth source/drain region 164.

The fourth source/drain contact 173 may be electrically connected to the third gate structure GS3. For example, a second shared contact SC2 may be formed on the third gate structure GS3 and the fourth source/drain contact 173. The second shared contact SC2 may extend in the second direction Y to connect the gate electrode 130 of the third gate structure GS3 with the fourth source/drain contact 173. An output node (i.e., the fourth source/drain contact 173) of the second inverter INV2 of the first cell MC1 may be connected to an input node (i.e., the third gate structure GS3) of the first inverter INV1 of the first cell MC1 through the second shared contact SC2.

The fifth source/drain contact 174 may be connected to the fourth active pattern AP4. For example, the fifth source/drain contact 174 may be in contact with the fourth source/drain region 164 on one side of the fourth gate structure GS4. The fourth gate structure GS4 may be interposed between the fourth source/drain contact 173 and the fifth source/drain contact 174.

The sixth source/drain contact 175 may be connected to the third active pattern AP3. For example, the sixth source/drain contact 175 may be in contact with the third source/drain region 163 between the second gate structure GS2 and the sixth gate structure GS6. In some embodiments, the sixth source/drain contact 175 may be disposed at the boundary between the first cell MC1 and the second cell MC2. The first cell MC1 and the second cell MC2 may share the sixth source/drain contact 175.

The seventh source/drain contact 176 may be interposed between the fifth gate structure GS5 and the seventh gate structure GS7, and between the sixth gate structure GS6 and the seventh gate structure GS7. The seventh source/drain contact 176 may connect the first active pattern AP1 with the second active pattern AP2. For example, the seventh source/drain contact 176 may extend in the first direction X to contact both the first source/drain region 161 and the second source/drain region 162.

The seventh source/drain contact 176 may be electrically connected to the sixth gate structure GS6. For example, a third shared contact SC3 may be formed on the sixth gate structure GS6 and the seventh source/drain contact 176. The third shared contact SC3 may extend in the second direction Y to connect the gate electrode 130 of the sixth gate structure GS6 with the seventh source/drain contact 176. An output node (i.e., the seventh source/drain contact 176) of the first inverter INV1 of the second cell MC2 may be connected to an input node (i.e., the sixth gate structure GS6) of the second inverter INV2 of the second cell MC2 through the third shared contact SC3.

The eighth source/drain contact 177 may be connected to the second active pattern AP2. For example, the eighth source/drain contact 177 may be in contact with the second source/drain region 162 on one side of the seventh gate structure GS7. The seventh gate structure GS7 may be interposed between the seventh source/drain contact 176 and the eighth source/drain contact 177.

The ninth source/drain contact 178 may be interposed between the sixth gate structure GS6 and the seventh gate structure GS7, and between the sixth gate structure GS6 and the eighth gate structure GS8. The ninth source/drain contact 178 may connect the third active pattern AP3 with the fourth active pattern AP4. For example, the ninth source/drain contact 178 may extend in the first direction X to contact both the third source/drain region 163 and the fourth source/drain region 164.

The ninth source/drain contact 178 may be electrically connected to the seventh gate structure GS7. For example, a fourth shared contact SC4 may be formed on the seventh gate structure GS7 and the ninth source/drain contact 178. The fourth shared contact SC4 may extend in the second direction Y to connect the gate electrode 130 of the seventh gate structure GS7 with the ninth source/drain contact 178. An output node (i.e., the ninth source/drain contact 178) of the second inverter INV2 of the second cell MC2 may be connected to an input node (i.e., the seventh gate structure GS7) of the first inverter INV1 of the second cell MC2 through the fourth shared contact SC4.

The tenth source/drain contact 179 may be connected to the fourth active pattern AP4. For example, the tenth source/drain contact 179 may be in contact with the fourth source/drain region 164 on one side of the eighth gate structure GS8. The eighth gate structure GS8 may be interposed between the ninth source/drain contact 178 and the tenth source/drain contact 179.

The first interlayer insulating film ID1 may fill a space on the sides of the first to eighth gate structures GS1 to GS8. For example, the first interlayer insulating film ID1 may cover the first to fourth source/drain regions 161 to 164. The second interlayer insulating film ID2 may be formed on the first to eighth gate structures GS1 to GS8 and the first interlayer insulating film ID1.

Each of the first interlayer insulating film ID1 and the second interlayer insulating film ID2 may include at least one of, for example, silicon oxide, silicon nitride, silicon oxynitride, silicon oxycarbide, silicon boron nitride, silicon boron carbonitride, silicon oxycarbonitride or a low dielectric constant material (i.e., a low-K dielectric) having a dielectric constant lower than that of silicon oxide, but embodiments are not limited thereto.

The frontside region FR may be formed on the first surface 100a of the substrate 100. The frontside region FR may include a first-level frontside wiring FM1 and a second-level frontside wiring FM2. For example, an inter-wire insulating layer 200 may be formed on the second interlayer insulating film ID2. The first-level frontside wiring FM1 and the second-level frontside wiring FM2 may be formed in the inter-wire insulating layer 200 to form an electrical path.

The first-level frontside wiring FM1 and the second-level frontside wiring FM2 may be sequentially stacked on the first surface 100a of the substrate 100. That is, the second-level frontside wiring FM2 may be disposed at a higher level than the first-level frontside wiring FM1. In the frontside region FR, “disposed at a higher-level” means “disposed to be far away from the substrate 100 in the third direction Z”. For example, in the third direction Z, the second-level frontside wiring FM2 may be more spaced apart from the first surface 100a than the first-level frontside wiring FM1.

In some embodiments, the first-level frontside wiring FM1 may include first to fifth frontside wiring patterns 211 to 215. The first to fifth frontside wiring patterns 211 to 215 may be disposed at the same level. The first to fifth frontside wiring patterns 211 to 215 may be sequentially arranged along the first direction X. Each of the first to fifth frontside wiring patterns 211 to 215 may extend to be long in the second direction Y.

The first frontside wiring pattern 211 may be connected to the first gate structure GS1. For example, a first gate contact 191, which is in contact with the gate electrode 130 of the first gate structure GS1 by passing through the second interlayer insulating film ID2 and the gate capping layer 150, may be formed. The first frontside wiring pattern 211 may be connected to the first gate structure GS1 through the first gate contact 191.

The second frontside wiring pattern 212 may be connected to the first source/drain contact 170. For example, a first contact via 180, which is in contact with the first source/drain contact 170 by passing through the second interlayer insulating film ID2, may be formed. The second frontside wiring pattern 212 may be connected to the first source/drain contact 170 through the first contact via 180.

In some embodiments, the second frontside wiring pattern 212 may extend to be long in the second direction Y beyond the first cell MC1 and the second cell MC2. The second frontside wiring pattern 212 may be provided as a bit line BL, and may be connected in common to the first pass transistor PS1 of the first cell MC1 and the first pass transistor PS1 of the second cell MC2.

The third frontside wiring pattern 213 may be connected to the third source/drain contact 172, the sixth source/drain contact 175 and the eighth source/drain contact 177. For example, a second contact via 182, which is in contact with the third source/drain contact 172 by passing through the second interlayer insulating film ID2, may be formed, a third contact via 185, which is in contact with the sixth source/drain contact 175 by passing through the second interlayer insulating film ID2, may be formed, and a fourth contact via 187, which is in contact with the eighth source/drain contact 177 by passing through the second interlayer insulating film ID2, may be formed. The third frontside wiring pattern 213 may be connected to the third source/drain contact 172 through the second contact via 182, may be connected to the sixth source/drain contact 175 through the third contact via 185, and may be connected to the eighth source/drain contact 177 through the fourth contact via 187.

In some embodiments, the third frontside wiring pattern 213 may extend to be long in the second direction Y beyond the first cell MC1 and the second cell MC2. The third frontside wiring pattern 213 may be provided as a first power line for applying a first power voltage (e.g., VDD) to the first pull-up transistor PU1 and the second pull-up transistor PU2.

The fourth frontside wiring pattern 214 may be connected to the fifth source/drain contact 174 and the tenth source/drain contact 179. For example, a fifth contact via 184, which is in contact with the fifth source/drain contact 174 by passing through the second interlayer insulating film ID2, may be formed, and a sixth contact via 189, which is in contact with the tenth source/drain contact 179 by passing through the second interlayer insulating film ID2, may be formed. The fourth frontside wiring pattern 214 may be connected to the fifth source/drain contact 174 through the fifth contact via 184, and may be connected to the tenth source/drain contact 179 through the sixth contact via 189.

In some embodiments, the fourth frontside wiring pattern 214 may extend to be long in the second direction Y beyond the first cell MC1 and the second cell MC2. The fourth frontside wiring pattern 214 may be provided as a complementary bit line/BL, and may be connected in common to the second pass transistor PS2 of the second cell MC2 and the second pass transistor PS2 of the second cell MC2.

The fifth frontside wiring pattern 215 may be connected to the fourth gate structure GS4. For example, a second gate contact 194, which is in contact with the gate electrode 130 of the fourth gate structure GS4 by passing through the second interlayer insulating film ID2 and the gate capping layer 150, may be formed. The fifth frontside wiring pattern 215 may be connected to the gate electrode 130 of the fourth gate structure GS4 through the second gate contact 194.

In some embodiments, the second-level frontside wiring FM2 may include a sixth frontside wiring pattern 230. The sixth frontside wiring pattern 230 may extend to be long in the first direction X.

The sixth frontside wiring pattern 230 may be connected to the first frontside wiring pattern 211 and the fifth frontside wiring pattern 215. For example, a first frontside via pattern 221 connecting the first frontside wiring pattern 211 with the sixth frontside wiring pattern 230 may be formed, and a second frontside via pattern 225 connecting the fifth frontside wiring pattern 215 with the sixth frontside wiring pattern 230 may be formed.

In some embodiments, the sixth frontside wiring pattern 230 may extend to be long in the first direction X beyond the first cell MC1 and the second cell MC2. The sixth frontside wiring pattern 230 may be provided as the first word line WL1 and may be connected in common to the gate (i.e., the first gate structure GS1) of the first pass transistor PS1 of the first cell MC1 and the gate (i.e., the fourth gate structure GS4) of the second pass transistor PS2 of the first cell MC1.

In some embodiments, the sixth frontside wiring pattern 230 may be formed over the first cell MC1 and the second cell MC2. For example, the sixth frontside wiring pattern 230 may overlap both the first cell MC1 and the second cell MC2 in the third direction Z.

In some embodiments, a width W1 of the sixth frontside wiring pattern 230 may be greater than or equal to about 2 CPP and less than about 4 CPP. For example, the width W1 of the sixth frontside wiring pattern 230 may be about 2 CPP to 3.5 CPP, or about 2 CPP to 3 CPP.

A backside region BR may be formed on the second surface 100b of the substrate 100. The backside region BR may include a first-level backside wiring BM1 and a second-level backside wiring BM2. For example, the backside inter-wire insulating film 300 may be formed on the second surface 100b of the substrate 100. The first-level backside wiring BM1 and the second-level backside wiring BM2 may be formed in the backside inter-wire insulating film 300 to form an electrical path.

The first-level backside wiring BM1 and the second-level backside wiring BM2 may be sequentially stacked on the second surface 100b of the substrate 100. That is, the second-level backside wiring BM2 may be disposed at a higher level than the first-level backside wiring BM1. In the backside region BR, “disposed at a higher level” means “disposed to be far away from the substrate 100 in the vertical direction (hereinafter, referred to as the third direction Z)”. For example, in the third direction Z, the second-level backside wiring BM2 may be more spaced apart from the second surface 100b than the first-level backside wiring BM1.

In some embodiments, the first-level backside wiring BM1 may include first to fourth backside wiring patterns 310 to 313. The first to fourth backside wiring patterns 310 to 313 may be disposed at the same level.

The first backside wiring pattern 310 may be connected to the fifth gate structure GS5 and the eighth gate structure GS8. For example, a first backside gate contact 395, which is in contact with the gate electrode 130 of the fifth gate structure GS5 by passing through the substrate 100 and the gate dielectric film 120, may be formed. Also, a second backside gate contact 398, which is in contact with the gate electrode 130 of the eighth gate structure GS8 by passing through the substrate 100 and the gate dielectric film 120, may be formed. The first backside wiring pattern 310 may be connected to the fifth gate structure GS5 through the first backside gate contact 395, and may be connected to the eighth gate structure GS8 through the second backside gate contact 398.

In some embodiments, the first backside gate contact 395 may not overlap the first active pattern AP1 in the third direction Z. For example, the first backside gate contact 395 may be in contact with the gate electrode 130 of the fifth gate structure GS5 by passing through the substrate 100, the field insulating film 105 and the gate dielectric film 120

In some embodiments, the second backside gate contact 398 may not overlap the fourth active pattern AP4 in the third direction Z. For example, the second backside gate contact 398 may be in contact with the gate electrode 130 of the eighth gate structure GS8 by passing through the substrate 100, the field insulating film 105 and the gate dielectric film 120.

In some embodiments, the first backside wiring pattern 310 may extend to be long in the first direction X beyond the first cell MC1 and the second cell MC2. The first backside wiring pattern 310 may be provided as the second word line WL2, and may be connected in common to the gate (i.e., the fifth gate structure GS5) of the first pass transistor PS1 of the second cell MC2 and the gate (i.e., the eighth gate structure GS8) of the second pass transistor PS2 of the second cell MC2.

In some embodiments, the first backside wiring pattern 310 may be formed over the first cell MC1 and the second cell MC2. For example, the first backside wiring pattern 310 may overlap both the first cell MC1 and the second cell MC2 in the third direction Z.

In some embodiments, at least a portion of the first backside wiring pattern 310 may overlap at least a portion of the sixth frontside wiring pattern 230 in the third direction Z. In this regard, the first cell MC1 and the second cell MC2 may be provided between the sixth frontside wiring pattern 230 and the first backside wiring pattern 310.

In some embodiments, a maximum width W2m of the first backside wiring pattern 310 may be greater than or equal to about 2 CPP and less than 4 CPP. For example, the maximum width W2m of the first backside wiring pattern 310 may be about 2 CPP to about 3.5 CPP, or about 2 CPP to about 3 CPP.

In some embodiments, the first backside wiring pattern 310 may include a first portion 310a, a second portion 310b, and a third portion 310c. The first portion 310a may extend in the first direction X. The second portion 310b may extend in the first direction X, and may be connected to one side of the first portion 310a. The third portion 310c may extend in the first direction X, and may be connected to the other side of the second portion 310b. The second portion 310b and the third portion 310c may be spaced apart from each other in the second direction Y.

The first portion 310a of the first backside wiring pattern 310 may be connected to the fifth gate structure GS5. For example, the first backside gate contact 395 may directly connect the first portion 310a with the fifth gate structure GS5.

The third portion 310c of the first backside wiring pattern 310 may be connected to the eighth gate structure GS8. For example, the second backside gate contact 398 may directly connect the third portion 310c with the eighth gate structure GS8.

In some embodiments, a width W2a of the first portion 310a may be about 1 CPP to about 3 CPP, or about 1.5 CPP to about 2.5 CPP, or about 1.5 CPP to about 2 CPP.

In some embodiments, a width W2b of the second portion 310b and a width W2c of the third portion 310c may be about 0.5 CPP to about 1.5 CPP, or about 0.7 CPP to about 1.3 CPP, or about 0.8 CPP to about 1.2 CPP. The width W2b of the second portion 310b and the width W2c of the third portion 310c are shown as being the same as each other, but embodiments are not limited thereto, and the width W2b of the second portion 310b and the width W2c of the third portion 310c may be different from each other.

The second backside wiring pattern 311 may be connected to the first active pattern AP1. For example, a first backside source/drain contact 371 which is in contact with the first source/drain region 161 on one side of the third gate structure GS3 may be formed. The first backside source/drain contact 371 may connect the second backside wiring pattern 311 with the first source/drain region 161 by passing through the substrate 100 and the fin pattern 110. The third gate structure GS3 may be interposed between the second source/drain contact 171 and the first backside source/drain contact 371.

The third backside wiring pattern 312 may be connected to the first active pattern AP1. For example, a second backside source/drain contact 373 which is in contact with the first source/drain region 161 on one side of the seventh gate structure GS7 may be formed. The second backside source/drain contact 373 may connect the third backside wiring pattern 312 with the first source/drain region 161 by passing through the substrate 100 and the fin pattern 110. The seventh gate structure GS7 may be interposed between the seventh source/drain contact 176 and the second backside source/drain contact 373.

The fourth backside wiring pattern 313 may be connected to the fourth active pattern AP4. For example, a third backside source/drain contact 372 which is in contact with the fourth source/drain region 164 between the second gate structure GS2 and the sixth gate structure GS6 may be formed. The third backside source/drain contact 372 may connect the fourth backside wiring pattern 313 with the fourth source/drain region 164 by passing through the substrate 100 and the fin pattern 110.

In some embodiments, the first portion 310a of the first backside wiring pattern 310 may be interposed between the second backside wiring pattern 311 and the third backside wiring pattern 312. Each of the second backside wiring pattern 311 and the third backside wiring pattern 312 may be spaced apart from the first portion 310a in the second direction Y. Also, the second backside wiring pattern 311 may be spaced apart from the second portion 310b in the first direction X, and the third backside wiring pattern 312 may be spaced apart from the third portion 310c in the first direction X.

In some embodiments, the fourth backside wiring pattern 313 may be interposed between the second portion 310b of the first backside wiring pattern 310 and the third portion 310c of the first backside wiring pattern 310. Each of the second portion 310b and the third portion 310c may be spaced apart from the fourth backside wiring pattern 313 in the second direction Y.

In some embodiments, the second-level backside wiring BM2 may include a fifth backside wiring pattern 330.

The fifth backside wiring pattern 330 may be connected to the second to fourth backside wiring patterns 311 to 313. For example, a first backside via pattern 321 connecting the second backside wiring pattern 311 with the fifth backside wiring pattern 330 may be formed, a second backside via pattern 322 connecting the third backside wiring pattern 312 with the fifth backside wiring pattern 330 may be formed, and a third backside via pattern 323 connecting the fourth backside wiring pattern 313 with the fifth backside wiring pattern 330 may be formed.

The fifth backside wiring pattern 330 may be provided as a second power line for applying a second power voltage (e.g., V_{SS}) different from the first power voltage (e.g., VDD) to the first pull-down transistor PD1 and the second pull-down transistor PD2.

In some embodiments, the fifth backside wiring pattern 330 may include a first extension portion 330a and a second extension portion 330b, which cross each other. For example, the first extension portion 330a may extend to be long in the second direction Y, and the second extension portion 330b may extend to be long in the first direction X.

The first extension portion 330a of the fifth backside wiring pattern 330 may be connected to the second backside wiring pattern 311 and the third backside wiring pattern 312. For example, the first backside via pattern 321 may directly connect the first extension portion 330a with the second backside wiring pattern 311, and the second backside via pattern 322 may directly connect the first extension portion 330a with the third backside wiring pattern 312.

The second extension portion 330b of the fifth backside wiring pattern 330 may be connected to the fourth backside wiring pattern 313. For example, the third backside via pattern 323 may directly connect the second extension portion 330b with the fourth backside wiring pattern 313.

As semiconductor devices become increasingly integrated, individual circuit patterns are becoming finer in order to increase density and implement more semiconductor devices in the same area. Accordingly, there is a problem that delay occurs in transmission of an electrical signal through wiring. For example, one word line may be provided per unit cell in one row in a cell array of a static random access memory (SRAM) device in which unit cells are arranged in the form of a matrix. In this case, a width of the word line may be limited to less than a width (e.g., 2 CPP) of one unit cell, and word line signal delay is intensified as a size of the unit cell is reduced.

In the semiconductor device according to some embodiments, the delay of the electrical signal may be reduced by using a backside power delivery network (BSPDN). In detail, as described above, in the semiconductor device according to some embodiments, the first word line WL1 (e.g., the sixth frontside wiring pattern 230) may be provided on the front side (i.e., the first surface 100a) of the substrate 100 and connected to the first cell MC1, and the second word line WL2 (e.g., the first backside wiring pattern 310) may be provided on the back side (i.e., the second surface 100b) of the substrate 100 and connected to the second cell MC2. Accordingly, each of a width of the first word line WL1 and a width of the second word line WL2 may not be limited to the width (e.g., 2 CPP) of one unit cell, and may be provided with a relatively wide width (e.g., about 2 CPP or more). Accordingly, the semiconductor device having improved performance by reducing word line signal delay may be provided.

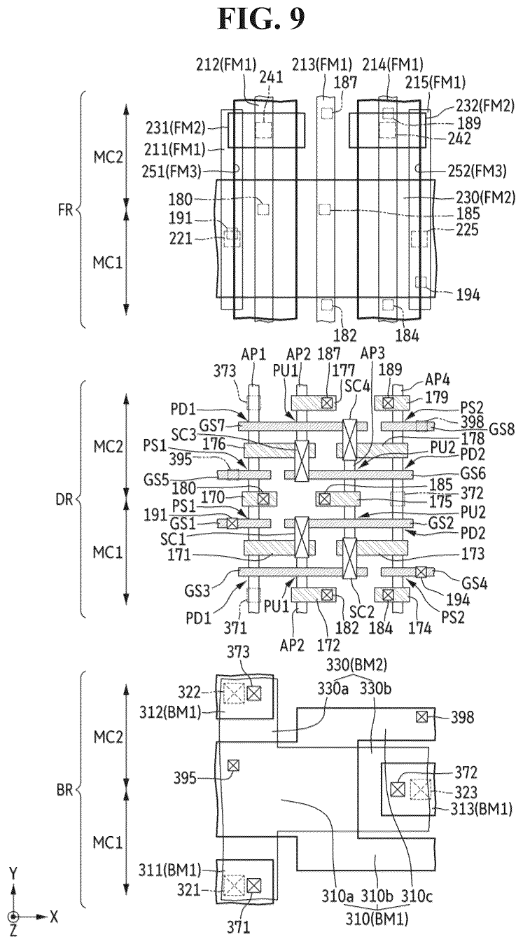

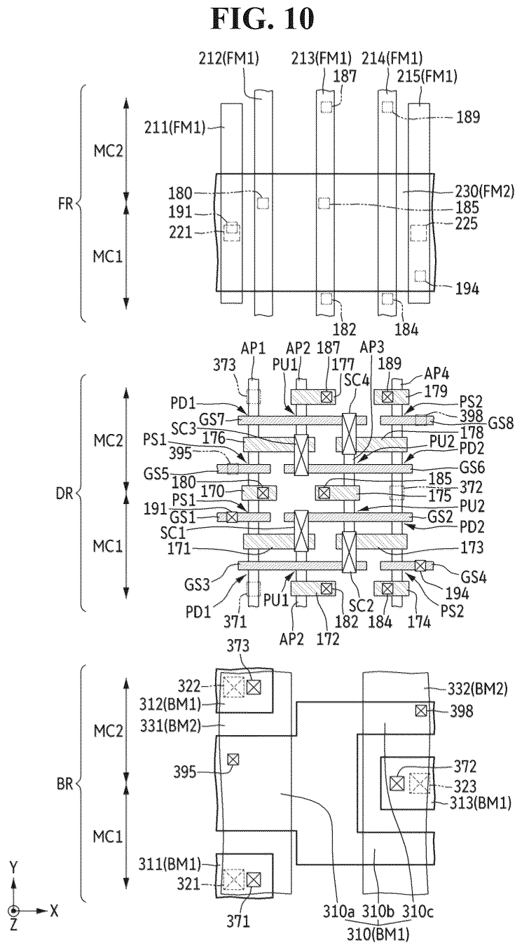

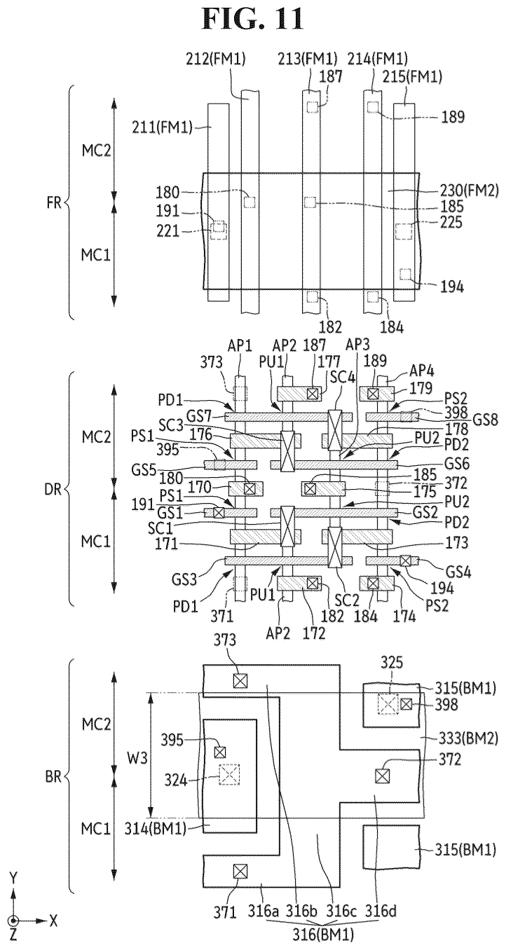

FIGS. 9 to 11 are various layout views illustrating a semiconductor device according to some embodiments. For convenience of description, redundant portions of those described above with reference to FIGS. 1 to 8 will be briefly described or omitted.

Referring to FIGS. 1, 2 and 9, in the semiconductor device according to some embodiments, the frontside region FR further includes a third-level frontside wiring FM3.

The third-level frontside wiring FM3 may be disposed at a higher level than the second-level frontside wiring FM2. The third-level frontside wiring FM3 may include a seventh frontside wiring pattern 251 and an eighth frontside wiring pattern 252. The seventh frontside wiring pattern 251 and the eighth frontside wiring pattern 252 may be disposed at the same level. The seventh frontside wiring pattern 251 and the eighth frontside wiring pattern 252 may be sequentially arranged along the first direction X. Each of the seventh frontside wiring pattern 251 and the eighth frontside wiring pattern 252 may extend to be long in the second direction Y.

The seventh frontside wiring pattern 251 may be connected to the second frontside wiring pattern 212. For example, the second-level frontside wiring FM2 may further include a first connection pattern 231 disposed at the same level as the sixth frontside wiring pattern 230. The first connection pattern 231 may be connected to the second frontside wiring pattern 212. Also, a third frontside via pattern 241 connecting the first connection pattern 231 with the seventh frontside wiring pattern 251 may be formed.

In some embodiments, the seventh frontside wiring pattern 251 may extend to be long in the second direction Y beyond the first cell MC1 and the second cell MC2. The seventh frontside wiring pattern 251 may provide a relatively wide bit line BL with respect to the second frontside wiring pattern 212.

The eighth frontside wiring pattern 252 may be connected to the fourth frontside wiring pattern 214. For example, the second-level frontside wiring FM2 may further include a second connection pattern 232 disposed at the same level as the sixth frontside wiring pattern 230. The second connection pattern 232 may be connected to the fourth frontside wiring pattern 214. Also, a fourth frontside via pattern 242 connecting the second connection pattern 232 with the eighth frontside wiring pattern 252 may be formed.

In some embodiments, the eighth frontside wiring pattern 252 may extend to be long in the second direction Y beyond the first cell MC1 and the second cell MC2. The eighth frontside wiring pattern 252 may provide a complementary bit line/BL with a relatively wide width compared with the fourth frontside wiring pattern 214. The sixth frontside wiring pattern 230 may be also connected to an upper level to provide the first word line WL1 with a wider width.

Referring to FIGS. 1, 2 and 10, in the semiconductor device according to some embodiments, the second-level backside wiring BM2 includes a sixth backside wiring pattern 331 and a seventh backside wiring pattern 332.

The sixth backside wiring pattern 331 and the seventh backside wiring pattern 332 may be arranged along the first direction X. Each of the sixth backside wiring pattern 331 and the seventh backside wiring pattern 332 may extend to be long in the second direction Y.

The sixth backside wiring pattern 331 may be connected to the second backside wiring pattern 311 and the third backside wiring pattern 312. For example, the first backside via pattern 321 may connect the second backside wiring pattern 311 with the sixth backside wiring pattern 331, and the second backside via pattern 322 may connect the third backside wiring pattern 312 with the sixth backside wiring pattern 331. In some embodiments, the sixth backside wiring pattern 331 may extend to be long in the second direction Y beyond the first cell MC1 and the second cell MC2.

The seventh backside wiring pattern 332 may be connected to the fourth backside wiring pattern 313. For example, the third backside via pattern 323 may connect the fourth backside wiring pattern 313 with the seventh backside wiring pattern 332. In some embodiments, the seventh backside wiring pattern 332 may extend to be long in the second direction Y beyond the first cell MC1 and the second cell MC2.

Each of the sixth backside wiring pattern 331 and the seventh backside wiring pattern 332 may be provided as a second power line for applying the second power voltage (e.g., V_{SS}).

Referring to FIGS. 1, 2 and 11, in the semiconductor device according to some embodiments, the first-level backside wiring BM1 includes eighth to tenth backside wiring patterns 316, 314 and 315, and the second-level backside wiring BM2 includes an eleventh backside wiring pattern 333.

The eighth backside wiring pattern 316 may be connected to the first backside source/drain contact 371, the second backside source/drain contact 373, and the third backside source/drain contact 372. The eighth backside wiring pattern 316 may be provided as a second power line for applying the second power voltage (e.g., V_{SS}).

In some embodiments, the eighth backside wiring pattern 316 may include a fourth portion 316a, a fifth portion 316b, a sixth portion 316c, and a seventh portion 316d. Each of the fourth portion 316a and the fifth portion 316b may extend in the first direction X. The fourth portion 316a and the fifth portion 316b may be spaced apart from each other in the second direction Y. The sixth portion 316c may extend in the second direction Y to connect the fourth portion 316a with the fifth portion 316b. The seventh portion 316d may extend from the sixth portion 316c in the first direction X. The sixth portion 316c may be connected between the fourth portion 316a and the seventh portion 316d, and between the fifth portion 316b and the seventh portion 316d.

The fourth portion 316a of the eighth backside wiring pattern 316 may be connected to the first backside source/drain contact 371. The fifth portion 316b of the eighth backside wiring pattern 316 may be connected to the second backside source/drain contact 373. The seventh portion 316d of the eighth backside wiring pattern 316 may be connected to the third backside source/drain contact 372.

The ninth backside wiring pattern 314 may be connected to the fifth gate structure GS5. For example, the first backside gate contact 395 may directly connect the ninth backside wiring pattern 314 with the fifth gate structure GS5.

In some embodiments, the ninth backside wiring pattern 314 may be interposed between the fourth portion 316a and the fifth portion 316b. Each of the fourth portion 316a and the fifth portion 316b may be spaced apart from the ninth backside wiring pattern 314 in the second direction Y. Also, the ninth backside wiring pattern 314 may be spaced apart from the sixth portion 316c in the first direction X.

The tenth backside wiring pattern 315 may be connected to the eighth gate structure GS8. For example, the second backside gate contact 398 may directly connect the tenth backside wiring pattern 315 with the eighth gate structure GS8.

In some embodiments, the tenth backside wiring pattern 315 may be spaced apart from the seventh portion 316d in the second direction Y. Also, the tenth backside wiring pattern 315 may be spaced apart from the sixth portion 316c in the first direction X.

The eleventh backside wiring pattern 333 may be connected to the ninth backside wiring pattern 314 and the tenth backside wiring pattern 315. For example, a fourth backside via pattern 324 connecting the ninth backside wiring pattern 314 with the eleventh backside wiring pattern 333 may be formed, and a fifth backside via pattern 325 connecting the tenth backside wiring pattern 315 with the eleventh backside wiring pattern 333 may be formed.

In some embodiments, the eleventh backside wiring pattern 333 may extend to be long in the first direction X beyond the first cell MC1 and the second cell MC2. The eleventh backside wiring pattern 333 may be provided as the second word line WL2 and connected in common to the gate (i.e., the fifth gate structure GS5) of the first pass transistor PS1 of the second cell MC2 and the gate (i.e., the eighth gate structure GS8) of the second pass transistor PS2 of the second cell MC2.

In some embodiments, the eleventh backside wiring pattern 333 may be formed over the first cell MC1 and the second cell MC2. For example, the eleventh backside wiring pattern 333 may overlap both the first cell MC1 and the second cell MC2 in the third direction Z.

In some embodiments, at least a portion of the eleventh backside wiring pattern 333 may overlap at least a portion of the sixth frontside wiring pattern 230 in the third direction Z.

In some embodiments, a width W3 of the eleventh backside wiring pattern 333 may be greater than or equal to about 2 CPP and less than 4 CPP. For example, the width W3 of the eleventh backside wiring pattern 333 may be about 2 CPP to 3.5 CPP, or about 2 CPP to about 3 CPP.

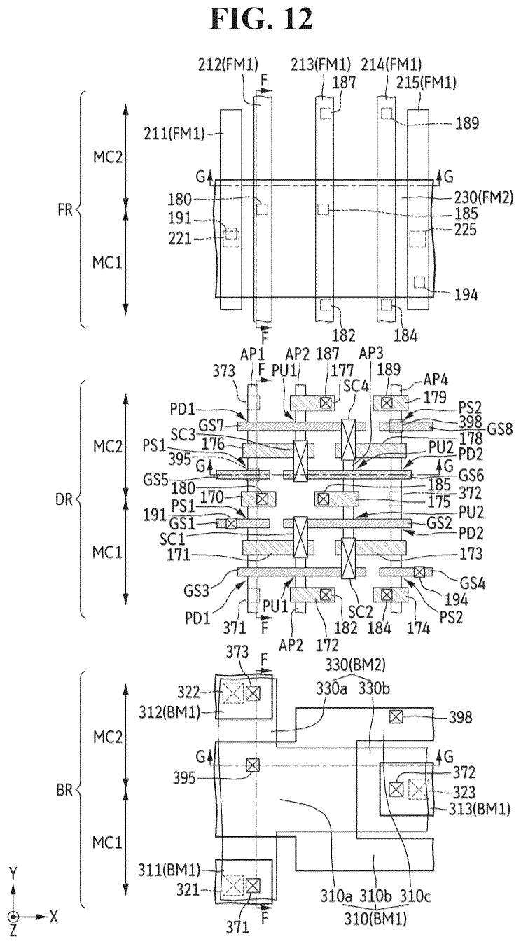

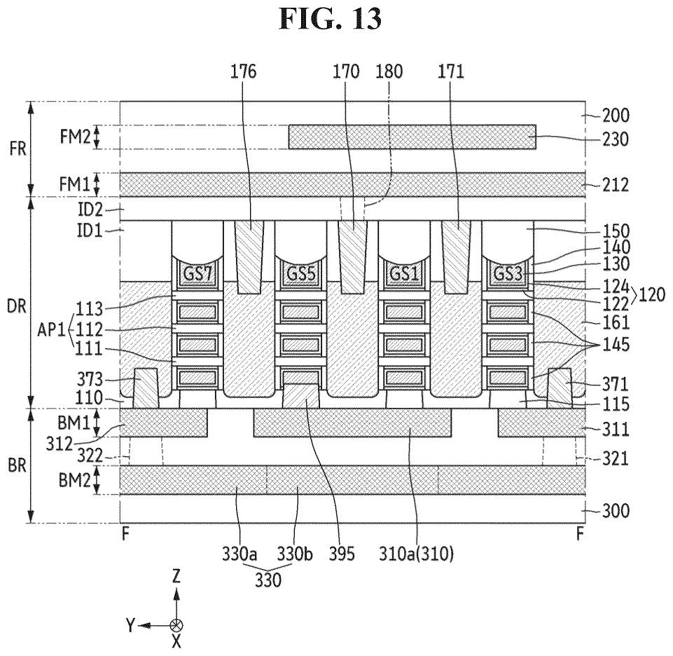

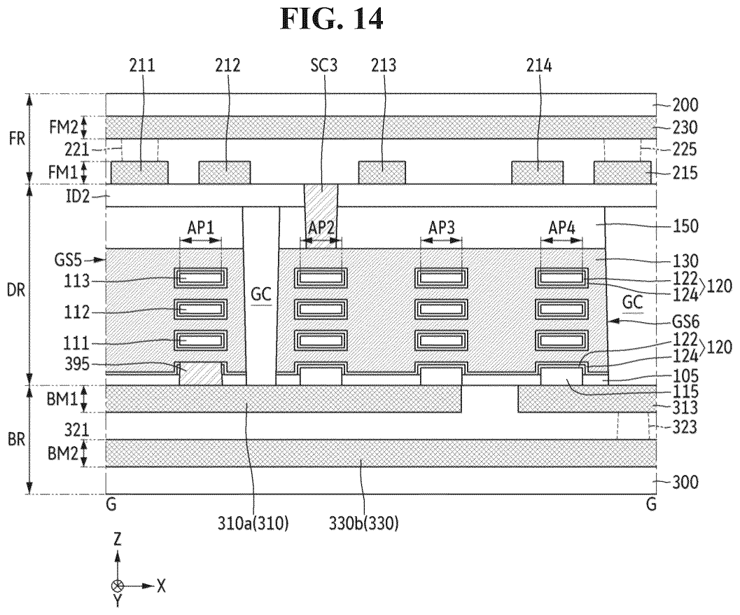

FIG. 12 is a layout view illustrating a semiconductor device according to some embodiments. FIG. 13 is a schematic cross-sectional view taken along line F-F of FIG. 12. FIG. 14 is a schematic cross-sectional view taken along line G-G of FIG. 12. For convenience of description, redundant portions of those described above with reference to FIGS. 1 to 8 will be briefly described or omitted.

Referring to FIGS. 1, 2 and 12 to 14, in the semiconductor device according to some embodiments, the first backside gate contact 395 overlaps the first active pattern AP1 in the third direction Z, and the second backside gate contact 398 overlaps the fourth active pattern AP4 in the third direction Z.

For example, the first backside gate contact 395 may be in contact with the gate electrode 130 of the fifth gate structure GS5 by passing through the fin pattern 110 below the first active pattern AP1. For example, the second backside gate contact 398 may be in contact with the gate electrode 130 of the eighth gate structure GS8 by passing through the fin pattern 110 below the fourth active pattern AP4.

In some embodiments, a sacrificial pattern 115 may be formed in the fin pattern 110. The sacrificial pattern 115 may be formed in the fin pattern 110 below the first to eighth gate structures GS1 to GS8.

The sacrificial pattern 115 may include an insulating material, for example, at least one of silicon oxide, silicon nitride, silicon oxynitride, silicon oxycarbide, silicon boron nitride, silicon boron carbonitride, silicon oxycarbonitride or a combination thereof, but embodiments are not limited thereto.

In some embodiments, the sacrificial pattern 115 may include a material having etch selectivity with respect to the fin pattern 110. For example, the fin pattern 110 may include a silicon oxide layer, and the sacrificial pattern 115 may include a silicon nitride layer. In some embodiments, the first backside gate contact 395 and the second backside gate contact 398 may be in contact with the gate electrode 130 by passing through a portion of the sacrificial pattern 115.

In some embodiments, the substrate 100 described with reference to FIGS. 4 to 8 may be omitted. For example, the substrate 100 may be removed in a thinning process for implementing the backside region BR. In this case, in the present specification, the fin pattern 110 and/or the sacrificial pattern 115 may be also referred to as a substrate for providing the device region DR.

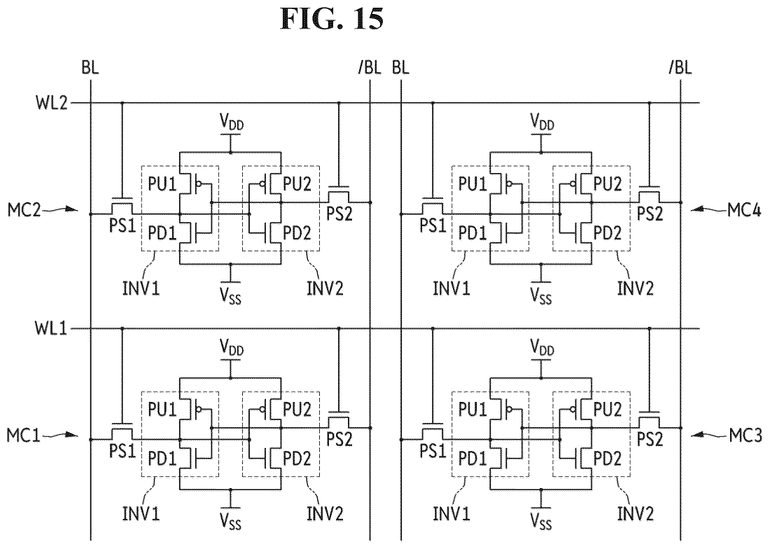

FIG. 15 is a circuit view illustrating a semiconductor device according to some embodiments. For convenience of description, redundant portions of those described above with reference to FIGS. 1 to 14 will be briefly described or omitted.

Referring to FIGS. 1 and 15, the semiconductor device according to some embodiments includes first to fourth cells MC1 to MC4 adjacent to each other.

Each of the first to fourth cells MC1 to MC4 may correspond to one of a plurality of unit SRAM cells MC. The first cell MC1 and the second cell MC2 may be adjacent to each other in the second direction Y. The first cell MC1 and the third cell MC3 may be adjacent to each other in the first direction X. The second cell MC2 and the fourth cell MC4 may be adjacent to each other in the first direction X, and the third cell MC3 and the fourth cell MC4 may be adjacent to each other in the second direction Y.

Each of the first to fourth cells MC1 to MC4 may include a pair of inverters INV1 and INV2 connected in parallel between the power node VDD and the ground node V_{SS}, and a first pass transistor PS1 and a second pass transistor PS2, which are connected to the output node of each of the inverters INV1 and INV2. Because each of the first to fourth cells MC1 to MC4 is the same as that described above with reference to FIG. 2, a detailed description thereof will be omitted below.

In some embodiments, the first cell MC1 and the third cell MC3 may share a first word line WL1, and the second cell MC2 and the fourth cell MC4 may share a second word line WL2. For example, the gates of the pass transistors PS1 and PS2 of the first cell MC1 and the gates of the pass transistors PS1 and PS2 of the third cell MC3 may be connected in common to one first word line WL1. For example, the gates of the pass transistors PS1 and PS2 of the second cell MC2 and the gates of the pass transistors PS1 and PS4 of the fourth cell MC4 may be connected in common to one second word line WL2.

In some embodiments, the first cell MC1 and the second cell MC2 may share one bit line BL and one complementary bit line/BL, and the third cell MC3 and the fourth cell MC4 may share the other bit line BL and the other complementary bit line/BL. For example, the first pass transistor PS1 of the first cell MC1 and the first pass transistor PS1 of the second cell MC2 may be connected in common to one bit line BL, and the second pass transistor PS2 of the first cell MC1 and the second pass transistor PS2 of the second cell MC2 may be connected in common to one complementary bit line/BL. For example, the first pass transistor PS1 of the third cell MC3 and the first pass transistor PS1 of the fourth cell MC4 may be connected in common to the other bit line BL, and the second pass transistor PS2 of the third cell MC3 and the second pass transistor PS2 of the fourth cell MC4 may be connected in common to the other complementary bit line/BL.

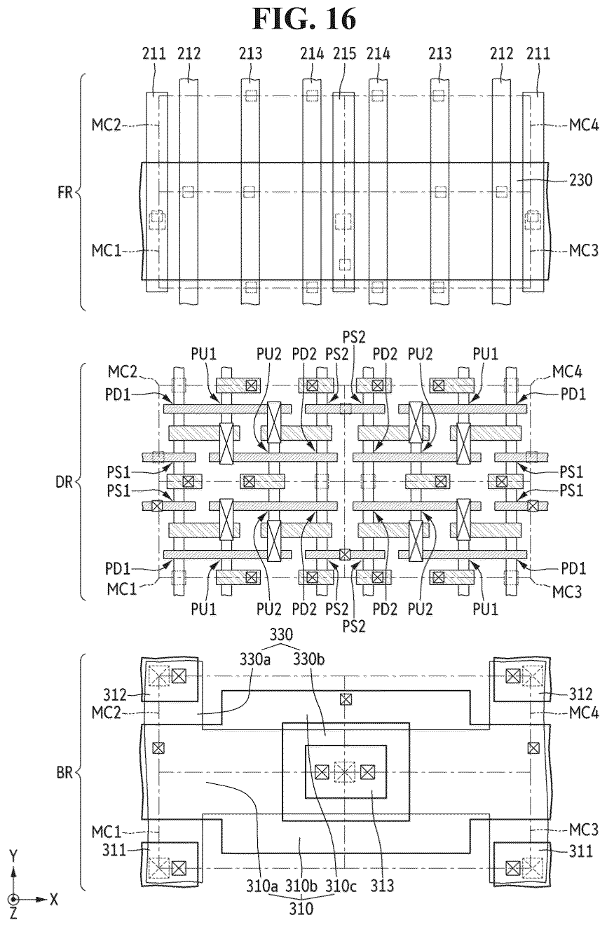

FIG. 16 is a layout view illustrating a semiconductor device according to some embodiments.

Referring to FIGS. 1, 2, 15 and 16, a semiconductor device according to some embodiments includes first to fourth cells MC1 to MC4.

The first cell MC1 and the second cell MC2 may correspond to the first cell MC1 and the second cell MC2, which are described with reference to FIGS. 1 to 14. For convenience of description, the first cell MC1 and the second cell MC2 of FIG. 16 are the same as the first cell MC1 and the second cell MC2 of FIG. 3.

The first cell MC1 and the third cell MC3 may be arranged in a planar symmetry relationship with respect to a boundary surface (e.g., YZ plane) between the first cell MC1 and the third cell MC3. The second cell MC2 and the fourth cell MC4 may be arranged in a planar symmetry relationship with respect to a boundary surface (e.g., YZ plane) between the second cell MC2 and the fourth cell MC4.

The second frontside wiring pattern 212 and the fourth frontside wiring pattern 214 may be repeatedly arranged in the first direction X. One second frontside wiring pattern 212 may extend in the second direction Y and provided as one bit line BL connected in common to the first cell MC1 and the second cell MC2. The other second frontside wiring pattern 212 may extend in the second direction Y and provided as another bit line BL connected in common to the third cell MC3 and the fourth cell MC4. One fourth frontside wiring pattern 214 may extend in the second direction Y and provided as one complementary bit line/BL connected in common to the first cell MC1 and the second cell MC2. The other fourth frontside wiring pattern 214 may extend in the second direction Y and provided as another complementary bit line/BL connected in common to the third cell MC3 and the fourth cell MC4.

The third frontside wiring pattern 213 may be repeatedly arranged in the first direction X. One third frontside wiring pattern 213 may extend in the second direction Y and provided as a first power line for applying a first power voltage (e.g., VDD) to the first cell MC1 and the second cell MC2. The other third frontside wiring pattern 213 may extend in the second direction Y and provided as a first power line for applying a first power voltage (e.g., VDD) to the third cell MC3 and the fourth cell MC4.

The sixth frontside wiring pattern 230 may extend in the first direction X and provided as one first word line WL1 connected in common to the first cell MC1 and the third cell MC3. For example, the sixth frontside wiring pattern 230 may be shared by the first cell MC1 and the third cell MC3 through the first frontside wiring pattern 211 and the fifth frontside wiring pattern 215. In some embodiments, the first cell MC1 and the third cell MC3 may share the fifth frontside wiring pattern 215.

The first backside wiring pattern 310 may extend in the first direction X and provided as one second word line WL2 connected in common to the second cell MC2 and the fourth cell MC4.

The fifth backside wiring pattern 330 may be provided as a second power line for applying a second power voltage (e.g., V_{SS}) to the first to fourth cells MC4. For example, the fifth backside wiring pattern 330 may be shared by the first to fourth cells MC4 through the second to fourth backside wiring patterns 311 to 313. In some embodiments, the first to fourth cells MC4 may share the fourth backside wiring pattern 313.

While aspects of embodiments have been particularly shown and described, it will be understood that various changes in form and details may be made therein without departing from the spirit and scope of the following claims.

What is claimed is:

1. A semiconductor device comprising:
a substrate comprising a first surface and a second surface, which are opposite to each other;
a first word line extending along a first direction on the first surface;
a second word line extending along the first direction on the second surface;
a bit line and a complementary bit line, which extend in parallel along a second direction that crosses the first direction, on the substrate; and
a first cell and a second cell, which are adjacent to each other along the second direction, on the substrate,
wherein each of the first cell and the second cell comprises a latch circuit comprising a first inverter and a second inverter, a first pass transistor connecting an output node of the first inverter with the bit line, and a second pass transistor connecting an output node of the second inverter with the complementary bit line,
wherein the first word line is connected to a gate of the first pass transistor of the first cell and a gate of the second pass transistor of the first cell, and
wherein the second word line is connected to a gate of the first pass transistor of the second cell and a gate of the second pass transistor of the second cell.

2. The semiconductor device of claim 1, wherein the first word line overlaps the first cell and the second cell along a third direction crossing the first direction and the second direction.

3. The semiconductor device of claim 1, wherein the second word line overlaps the first cell and the second cell along a third direction crossing the first direction and the second direction.

4. The semiconductor device of claim 1, wherein the second word line comprises a first portion extending along the first direction, a second portion extending along the first direction from one side of the first portion, and a third portion extending along the first direction from the other side of the first portion and spaced apart from the second portion along the second direction.

5. The semiconductor device of claim 1, further comprising a first power line and a second power line, configured to provide different voltages, on the substrate,
wherein the first inverter and the second inverter are connected in parallel between the first power line and the second power line.

6. The semiconductor device of claim 5, wherein the first power line is on the first surface, and the second power line is on the second surface.

7. The semiconductor device of claim 6, wherein the bit line and the complementary bit line are arranged at a same level as the first power line along a third direction crossing the first direction and the second direction.

8. The semiconductor device of claim 6, wherein the second word line is arranged at a different level from the second power line along a third direction crossing the first direction and the second direction.

9. The semiconductor device of claim 6, wherein the second power line comprises a first extension portion extending along the second direction, and a second extension portion extending along the first direction.

10. A semiconductor device comprising:
a substrate comprising a first surface and a second surface, which are opposite to each other;
a plurality of unit static random access memory (SRAM) cells arranged in a matrix along first and second directions crossing each other, on the first surface;
a first word line extending along the first direction on the first surface; and
a second word line extending along the first direction on the second surface,
wherein the plurality of unit SRAM cells comprise first unit SRAM cells arranged in a first row and second unit SRAM cells arranged in a second row, each of the first and second rows extending along the first direction,
wherein the first word line is commonly connected to the first unit SRAM cells of the first row, and
wherein the second word line is commonly connected to the second unit SRAM cells of the second row.

11. The semiconductor device of claim 10, wherein the first row is one among a plurality of first rows, the second row is one among a plurality of second rows, and the plurality of first rows and the plurality of second rows are arranged alternately along the second direction.

12. The semiconductor device of claim 10, wherein the first word line and the second word line overlap each other along a third direction crossing the first direction and the second direction.

13. The semiconductor device of claim 10, further comprising a bit line and a complementary bit line, which extend in parallel along the second direction, on the first surface,
wherein each of the bit line and the complementary bit line is commonly connected to the first row and the second row.

14. The semiconductor device of claim 13, wherein each of the plurality of unit SRAM cells comprises a latch circuit comprising a first inverter and a second inverter, a first pass transistor connecting an output node of the first inverter with the bit line, and a second pass transistor connecting an output node of the second inverter with the complementary bit line,
wherein the first word line is connected to a gate of the first pass transistor of the plurality of unit SRAM cells in the first row and a gate of the second pass transistor of the plurality of unit SRAM cells in the first row, and
wherein the second word line is connected to a gate of the first pass transistor of the plurality of unit SRAM cells in the second row and a gate of the second pass transistor of the plurality of unit SRAM cells in the second row.

15. A semiconductor device comprising:
first and second cells adjacent to each other along a first direction;
a substrate comprising a first surface and a second surface, which are opposite to each other;
first to fourth active patterns, which are sequentially arranged along a second direction crossing the first direction, each of the first to fourth active patterns extending along the first direction on the first surface;
a first gate structure, which extends along the second direction across the first active pattern, in the first cell;
a second gate structure, which extends along the second direction across the third and fourth active patterns, in the first cell;
a third gate structure, which extends along the second direction across the first and second active patterns, in the first cell;
a fourth gate structure, which extends along the second direction across the fourth active pattern, in the first cell;
a first source/drain contact, which connects the first active pattern with the second active pattern and the second gate structure, between the first gate structure and the third gate structure, and between the second gate structure and the third gate structure;
a second source/drain contact, which connects the third active pattern with the fourth active pattern and the third gate structure, between the second gate structure and the third gate structure, and between the second gate structure and the fourth gate structure;
a fifth gate structure, which extends along the second direction across the first active pattern, in the second cell;
a sixth gate structure, which extends along the second direction across the third and fourth active patterns, in the second cell;
a seventh gate structure, which extends along the second direction across the first and second active patterns, in the second cell;
an eighth gate structure, which extends along the second direction across the fourth active pattern, in the second cell;
a third source/drain contact, which connects the first active pattern with the second active pattern and the sixth gate structure, between the fifth gate structure and the seventh gate structure, and between the sixth gate structure and the seventh gate structure;
a fourth source/drain contact, which connects the third active pattern with the fourth active pattern and the seventh gate structure, between the sixth gate structure and the seventh gate structure, and between the sixth gate structure and the eighth gate structure;
a first frontside wiring pattern, which extends along the second direction and is connected to the first and fourth gate structures, on the first surface; and
a first backside wiring pattern, which extends along the second direction and is connected to the fifth and eighth gate structures, on the second surface.

16. The semiconductor device of claim 15, further comprising:
a fifth source/drain contact, which is connected to the first active pattern, between the first gate structure and the fifth gate structure;
a sixth source/drain contact, which is connected to the fourth active pattern, the fourth gate structure being interposed between the second source/drain contact and the sixth source/drain contact;
a seventh source/drain contact, which is connected to the fourth active pattern, the eighth gate structure being interposed between the fourth source/drain contact and the seventh source/drain contact;
a second frontside wiring pattern, which extends along the first direction and is connected to the fifth source/drain contact, on the first surface; and
a third frontside wiring pattern, which extends along the first direction and is connected to the sixth and seventh source/drain contacts, on the first surface.

17. The semiconductor device of claim 15, wherein a width of the first frontside wiring pattern is greater than or equal to 2 contacted poly pitch (CPP) and less than 4 CPP.

18. The semiconductor device of claim 15, further comprising:
a first backside gate contact passing through the substrate, the first backside gate contact connecting the first backside wiring pattern with the fifth gate structure; and
a second backside gate contact passing through the substrate, the second backside gate contact connecting the first backside wiring pattern with the eighth gate structure.

19. The semiconductor device of claim 18, wherein the first backside wiring pattern comprises a first portion extending along the second direction, a second portion extending along the second direction from one side of the first portion, and a third portion extending along the second direction from the other side of the first portion and spaced apart from the second portion in the first direction,
wherein the first backside gate contact connects the first portion with the fifth gate structure, and
wherein the second backside gate contact connects the third portion with the eighth gate structure.

20. The semiconductor device of claim 15, wherein a maximum width of the first backside wiring pattern is greater than or equal to 2 contacted poly pitch (CPP) and less than 4 CPP.
